(19) United States
(12) Patent Application Publication
(10) Pub. No.: US 2010/0033249 A1
(43) Pub. Date: Feb. 11, 2010

(54) DIFFERENTIAL AMPLIFIER

(75) Inventor: Masahiro KUDO, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/537,332

(22) Filed: Aug. 7, 2009

(30) Foreign Application Priority Data
Aug. 8, 2008 (JP) 2008-205523

(51) Int. Cl. H03F 3/45

(52) U.S. Cl. 330/252

(57) ABSTRACT

A differential amplifier includes first and second transistors having source terminals coupled to each other at a first common node, a first common current source coupled to the first common node, and an in-phase signal input terminal configured to input, to the first common node, an in-phase signal of first and second input signals inputted to gate terminals of the first and second transistors.

### CROSS-REFERENCE TO RELATED APPLICATIONS

This application is based upon and claims the benefit of priority of the prior Japanese Patent Application No. 2008-205523, filed on Aug. 8, 2008, the entire contents of which are incorporated herein by reference.

### FIELD

The present invention relates to a differential amplifier.

### BACKGROUND

Differential amplifiers have hitherto been disclosed which output a differential signal with respect to two input signals (for example, Japanese Patent Laid-Open Patent Publication Nos. 7-154165, 10-126172 and 2007-228631).

FIG. 8 is a view illustrating an example of a configuration of a related art differential amplifier. A differential amplifier 200 includes two nMOS transistors 210 and 220, current source 230, and two resistive loads 240 and 250. The two nMOS transistors 210 and 220 constitute a differential pair; respective source terminals are coupled to the current source 230.

In the differential amplifier 200, the differential pair biased by the common current source 230 converts a differential component of input signals Vin+ and Vin− into a differential current and outputs the current. The differential current is converted into a voltage signal by the two resistive loads 240 and 250 and outputted as output signals Vout+ and Vout−. In this case, in the differential amplifier 200, the potential of the common node of the source terminals in the differential pair follows an in-phase component of input signals Vin+ and Vin−, and the in-phase component is suppressed in the output current at the drain terminal of the differential pair. Thus, output signals Vout+ and Vout− with the in-phase component of the input signals removed are provided.

In the related art differential amplifier 200, however, parasitic capacitance exists at the common node to which the source terminals of the nMOS transistors 210 and 220 are both coupled. The parasitic capacitance forms a low impedance for high-frequency signal such as Radio Frequency (RF) signal, and thus the potential of the common node of the source terminals does not perfectly follow, for example, an increase of in-phase component of input signals Vin+ and Vin−, so the in-phase component of input signals Vin+ and Vin− may not be suppressed. When output signals Vout+ and Vout− with unsuppressed in-phase components are outputted, signals of different frequency components may be disadvantageously outputted in a rear-stage signal processing circuit or the like.

### SUMMARY

According to an aspect of the invention, a differential amplifier includes first and second transistors having source terminals coupled to each other at a first common node, a first common current source coupled to the first common node, and an in-phase signal input terminal configured to input, to the first common node, an in-phase signal of first and second input signals inputted to gate terminals of the first and second transistors.

The objects and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a configuration of a differential amplifier;

FIG. 2 illustrates an example of a configuration of the differential amplifier including resistive loads;

FIG. 3 illustrates an example of a configuration of a differential amplifier including an in-phase signal output circuit;

FIGS. 4A and 4B illustrate experiment results;

FIG. 5 illustrates an example of a configuration of a differential amplifier including an in-phase signal output circuit and an in-phase signal buffer;

FIG. 6 illustrates an example of a configuration of the differential amplifier including a differential signal output circuit and in-phase signal generating circuit;

FIG. 7 illustrates another example of a configuration of differential amplifier; and

FIG. 8 illustrates an example of a configuration of a related art differential amplifier.

### DESCRIPTION OF EMBODIMENTS

Embodiments will be described below with reference to the drawings.

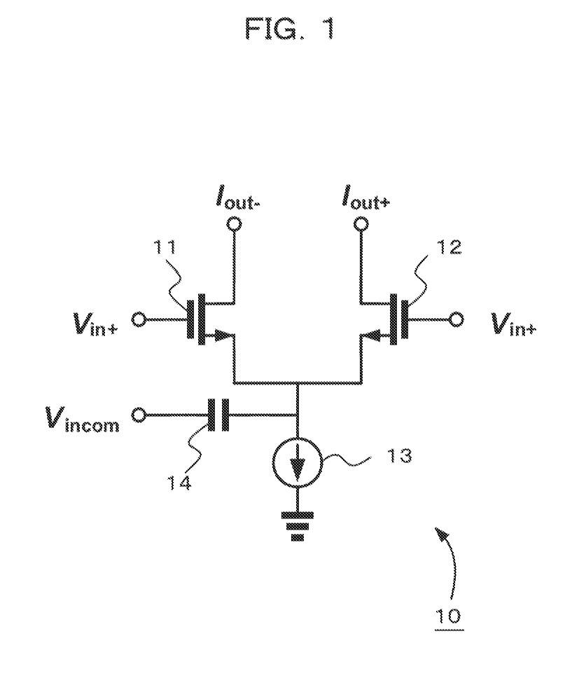

FIG. 1 illustrates an example of a configuration of a differential amplifier 10. The differential amplifier 10 includes two nMOS transistors 11 and 12, a common current source 13, and a capacitor 14.

The two nMOS transistors 11 and 12 make up a differential pair; respective source terminals are coupled to each other. Input signals Vin+ and Vin− are inputted to gate terminals of the nMOS transistors 11 and 12, respectively. Outputs Iout+ and Iout− are outputted from drain terminals.

One terminal of the common current source 13 is coupled to the common node of the source terminals of the nMOS transistors 11 and 12, and the other terminal is coupled to the ground.

One terminal of the capacitor 14 is coupled to the common node of the source terminals of the nMOS transistors 11 and 12, and an in-phase signal Vincom of two input signals Vin+ and Vin− is inputted via the other terminal (in-phase signal input terminal).

In this way, in the differential amplifier 10, the in-phase signal Vincom is inputted via the in-phase signal input terminal, so the common node is charged by the in-phase signal Vincom, and the potential of the common node follows the input signal in-phase component; thus the in-phase signal current of the differential pair may not vary. Accordingly, even when high-frequency input signals Vin+ and Vin− are inputted, the in-phase signal can be suppressed.

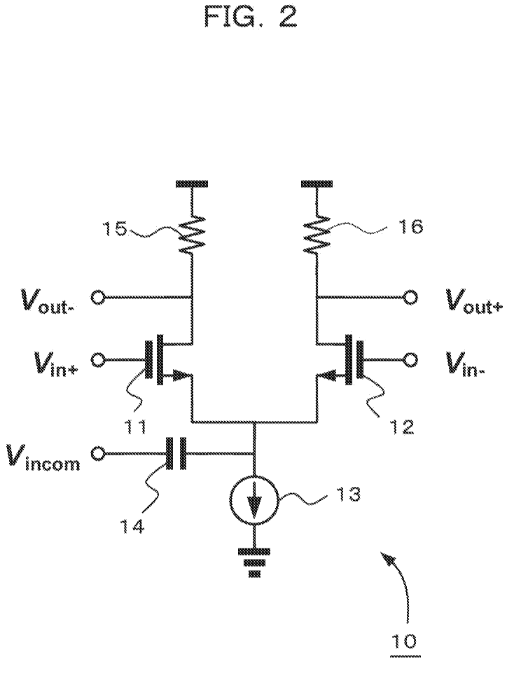

FIG. 2 is a view illustrating an example of a configuration of the differential amplifier 10 using resistive loads 15 and 16. The resistive loads 15 and 16 are coupled to drain terminals of the nMOS transistors 11 and 12, respectively. Output terminals are arranged between the two resistive loads 15 and 16 and the two nMOS transistors 11 and 12, and output signals Vout+ and Vout− are outputted from the output terminals. In the differential amplifier 10, a differential current signal is converted into a voltage signal by the two resistive loads 15 and 16, and output signals Vout+ and Vout− are outputted from the output terminals.

In the differential amplifier 10 illustrated in FIG. 2, similar to the example of FIG. 1, output signals Vout+ and Vout− with a suppressed high-frequency in-phase signal may be outputted.

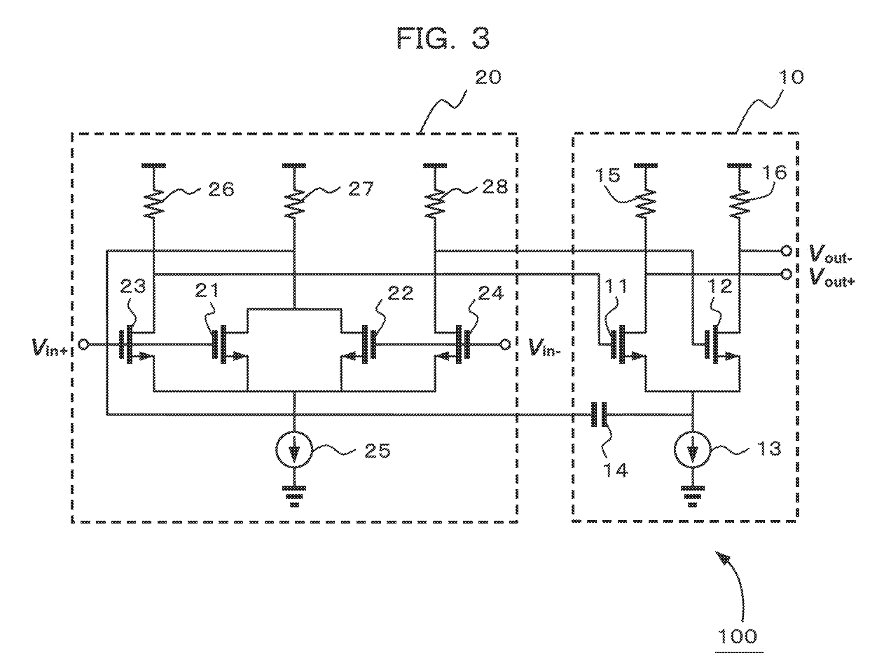

FIG. 3 is a view illustrating an example of a configuration of a differential amplifier circuit 100 including an in-phase signal output circuit 20 and a differential amplifier 10. The in-phase signal output circuit 20 is used to produce an in-phase signal Vincom inputted to the in-phase signal input terminal of the differential amplifier 10.

The in-phase signal output circuit 20 includes four nMOS transistors 21 to 24, three resistive loads 26 to 28, and a current source 25.

Source and drain terminals of the nMOS transistors 21 and 22 are coupled to each other, the source terminals are coupled to the current source 25, and the drain terminals are coupled to the resistive load 27.

Source terminals of the nMOS transistors 23 and 24 are both coupled to the common node of the source terminals of the nMOS transistors 21 and 22, the resistive load 26 is coupled to a drain terminal of the nMOS transistor 23, and the resistive load 28 is coupled to a drain terminal of the nMOS transistor 24.

One terminal of the current source 25 is coupled to the common node of the source terminals of the four nMOS transistors 21 to 24, and the other terminal is coupled to the ground.

Of the two input terminals to which input signals Vin+ and Vin− are inputted, one terminal is coupled to gate terminals of the two nMOS transistors 21 and 23, and the other terminal is coupled to gate terminals of the two nMOS transistors 22 and 24.

The in-phase signal Vincom is outputted from a point between the resistive load 27 and the common node of the drain terminals of the two nMOS transistors 21 and 22, and is inputted to the in-phase signal input terminal of the differential amplifier 10.

One signal of the differential signal is supplied from a point between the drain of the nMOS transistor 23 and the resistive load 26 to a gate of the nMOS transistor 11, and the other signal of the differential signal is supplied from a point between the drain of the nMOS transistor 24 and the resistive load 28 to a gate of the nMOS transistor 12.

In the in-phase signal output circuit 20, two input signals Vin+ and Vin− are added (or averaged) by the nMOS transistors 21 and 22 and the resistive load 27, so the in-phase signal Vincom of two input signals Vin+ and Vin− is outputted.

Accordingly, the in-phase signal output circuit 20 is coupled to the in-phase signal input terminal of the differential amplifier 10, whereby the in-phase signal output circuit 20 can supply the in-phase signal Vincom to the differential amplifier 10. Further, the in-phase signal output circuit 20 may also supply differential input signals to the differential amplifier 10 along with the in-phase signal Vincom.

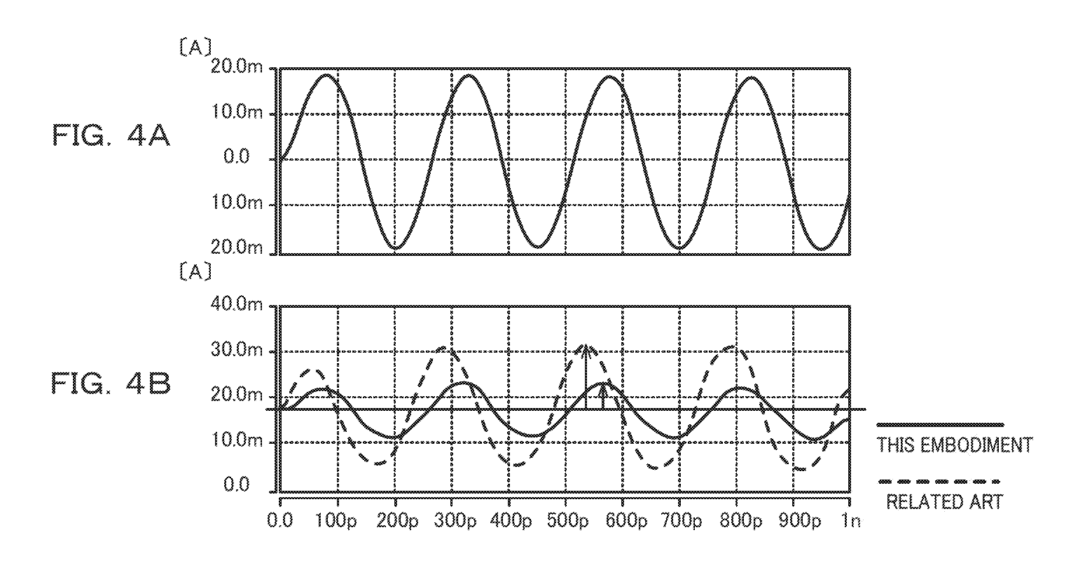

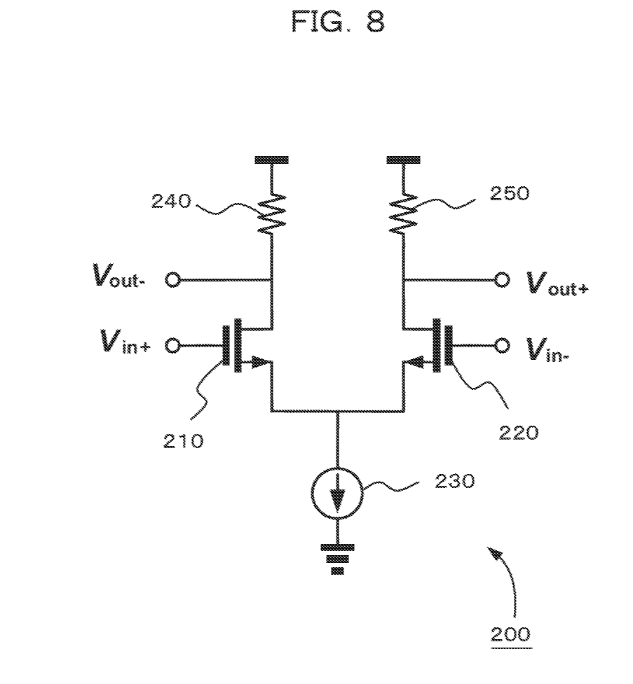

FIGS. 4A and 4B illustrate examples of results of simulation of the current outputted by the differential pair of the differential amplifier 10. In both the drawings, the abscissa indicates time, and the ordinate indicates the current. The bold-face line indicates simulation results of the differential amplifier 10, and the dashed line indicates simulation results of a related art differential amplifier (for example, illustrated in FIG. 8).

FIG. 4A illustrates a case in which a differential signal is inputted as two input signals Vin+ and Vin− to the differential amplifier 10 to produce differential outputs Vout+ and Vout−. As illustrated in FIG. 4A, when the differential signal Vin+ and Vin−was inputted, a differential output Vout+ and Vout− of the differential amplifier 10 had substantially the same characteristic as those of the related art.

However, as illustrated in FIG. 4B, when an in-phase signal was inputted as two input signals Vin+ and Vin− to the differential amplifier 10, the amplitude of the in-phase output signal was reduced to less than one half that of the related art.

As described above, when receiving a differential signal as the two input signals, the differential amplifier 10 can output the same differential output as that of the related art. And when receiving an in-phase signal as the two input signals, the differential amplifier 10 can output an in-phase signal with the amplitude reduced to less than one half that of the related art.

The above description is about the in-phase signal output circuit 20 illustrated in FIG. 3, which is an example of a circuit for producing the in-phase signal Vincom. As the circuit for producing the in-phase signal Vincom, there are various other configurations. Those various configurations will be described below.

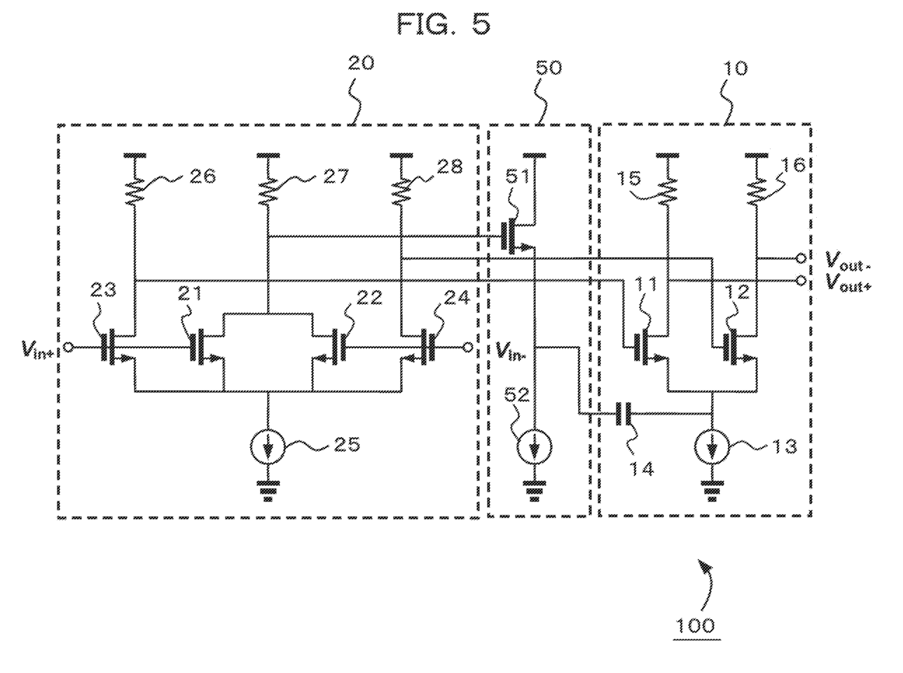

FIG. 5 is a view illustrating an example of a configuration of a differential amplifier circuit 100 including an in-phase signal buffer 50 between the differential amplifier 10 and the in-phase signal output circuit 20.

The in-phase signal buffer 50 includes an nMOS transistor 51 and a current source 52.

A gate terminal of the nMOS transistor 51 is coupled between the resistive load 27 of the in-phase signal output circuit 20 and the common drain terminal of the two nMOS transistors 21 and 22. A source terminal of the nMOS transistor 51 is coupled to the capacitor 14 of the differential amplifier 10 and also to the current source 52. The nMOS transistor 51 and the current source 52 make up an nMOS source follower working as a buffer which shifts an input voltage by a given voltage. The output impedance of the source follower is low, so the use of the in-phase signal buffer 50 can raise the capacity of charging the in-phase signal input terminal of the differential amplifier 10.

The in-phase signal buffer 50 produces a signal obtained by shifting, by the voltage level shift amount of the source follower, an in-phase signal component of input signals Vin+ and Vin− to the in-phase signal output circuit 20. The in-phase signal buffer 50 outputs the produced signal as the in-phase signal Vincom to the differential amplifier 10. The capacitor arranged at the in-phase signal input terminal of the differential amplifier 10 separates the in-phase signal buffer 50 and differential amplifier 10 with respect to a DC component. However, by designing the level shift amount of the in-phase signal buffer 50 to be equal to the gate-source voltage of the differential pair of the differential amplifier 10, even if the output of the in-phase signal buffer 50 is directly coupled to the common node of source terminals of the differential pair of the differential amplifier 10 without passing through the capacitor 14, the circuits (the transistor 11 of the differential amplifier 10, and the like) may operate at an ordinary operating point with DC component causing no interference. With such configuration, the capacitor 14, which typically requires a large area, may be omitted.

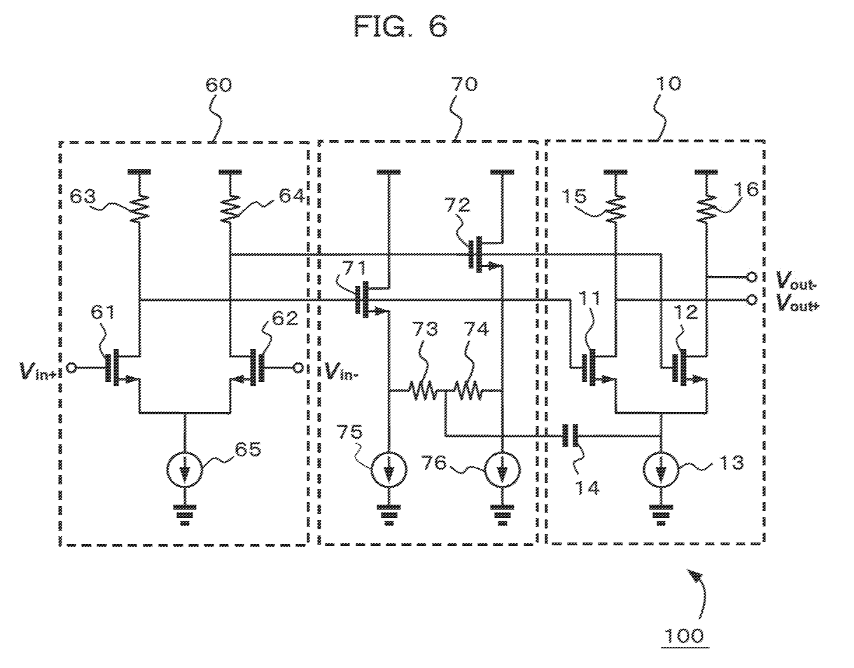

FIG. 6 illustrates an example of a configuration of the differential amplifier circuit 100 including a differential signal output circuit 60 and an in-phase signal generating circuit 70.

The differential signal output circuit 60 includes two nMOS transistors 61 and 62, two resistive loads 63 and 64, and a current source 65.

The two nMOS transistors 61 and 62 constitute a differential pair. Source terminals of the nMos transistors are coupled to each other, and the common node of the source terminals is coupled to the current source 65. Drain terminals of the nMOS transistors 61 and 62 are coupled to the resistive loads 63 and 64, respectively.

The in-phase signal generating circuit 70 includes two nMOS transistors 71 and 72, two resistive loads 73 and 74, and two current sources 75 and 76.

A gate terminal of the nMOS transistor 71 is coupled between the resistive load 63 of the differential signal output circuit 60 and the nMOS transistor 61, and a source terminal of the nMOS transistor 71 is coupled to the current source 75.

A gate terminal of the nMOS transistor 72 is coupled between the resistive load 64 of the differential signal output circuit 60 and the nMOS transistor 62, and a source terminal of the nMOS transistor 72 is coupled to the current source 76.

One terminal of the resistor 73 is coupled to the source terminal of the nMOS transistor 71, and the other terminal is coupled to one terminal of the resistor 74. The other terminal of the resistor 74 is coupled to the source terminal of the nMOS transistor 72. An intermediate node between the two resistors 73 and 74 is coupled to the capacitor 14 of the differential amplifier 10.

The two nMOS transistors 71 and 72 make up a source follower which, similarly to the above described example, functions as a buffer. In this example, the source follower works as a buffer to generate an intermediate potential of a differential signal outputted from the differential signal output circuit 60. As a result of generating an intermediate potential, an in-phase signal component obtained by averaging or adding two differential signals (input signals to the in-phase signal generating circuit 70) is generated at the intermediate node between the two resistors 73 and 74. The intermediate node is coupled to the in-phase signal input terminal of the differential amplifier 10, so the in-phase signal generating circuit 70 can supply the in-phase signal to the differential amplifier 10.

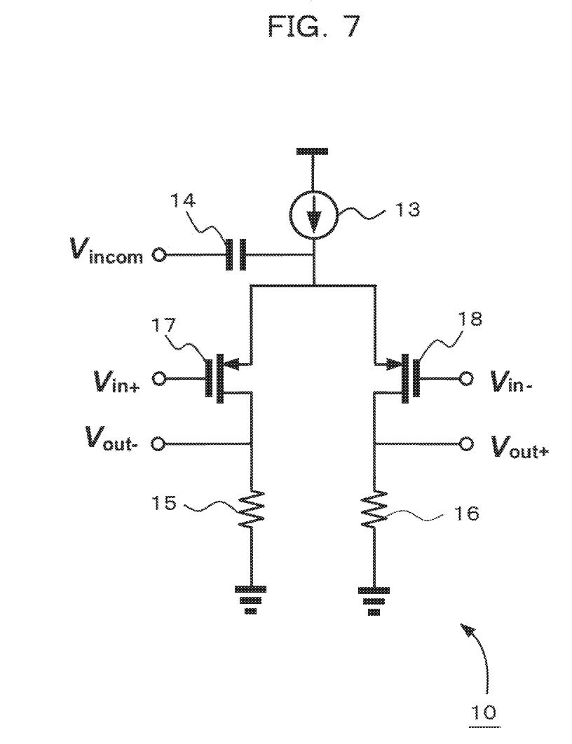

The above description is about the differential amplifier 10 which is an example in which nMOS is used as the MOS transistor. However, PMOS may also be used. FIG. 7 is a view illustrating an example of a configuration of a differential amplifier 10 using a PMOS transistor.

The differential amplifier 10 includes a common current source 13, a capacitor 14, two PMOS transistors 17 and 18, and two resistive loads 15 and 16.

Source terminals of the two PMOS transistors 17 and 18 are coupled to each other, and the common node is coupled via the capacitor 14 to an in-phase signal input terminal. Gate terminals of the two PMOS transistors 17 and 18 are coupled to input signal terminals. Drain terminals of the two PMOS transistors 17 and 18 are coupled to the resistive loads 15 and 16, respectively. The other terminals of the resistive loads 15 and 16 are both coupled to the ground.

In the differential amplifier 10 illustrated in FIG. 7, similar to the differential amplifier 10 illustrated in FIG. 1 and the like, the in-phase signal Vincom is inputted via the in-phase signal input terminal. Thus no in-phase signal current may be supplied from the differential pair made up of the two PMOS transistors 17 and 18, so an output signal with a suppressed in-phase signal is provided.

The above descriptions are examples in which the resistors 15 and 16 are used as the loads of the differential amplifier 10. However, elements such as transistors other than resistors may be used as the loads.

Further, instead of the nMOS transistor 21 and other nMOS transistors used in the in-phase signal output circuit 20, the in-phase signal buffer 50, the differential signal output circuit 60, and the in-phase signal generating circuit 70, elements such as PMOS transistors may be used to construct the differential amplifier.

According to one aspect of the present invention, a differential amplifier can be provided which outputs a signal with suppressed in-phase signal when receiving a high-frequency input signal.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

What is claimed is:

1. A differential amplifier comprising:
first and second transistors having source terminals coupled to each other at a first common node;
a first common current source coupled to the first common node; and
an in-phase signal input terminal configured to input, to the first common node, an in-phase signal of first and second input signals inputted to gate terminals of the first and second transistors.

2. The differential amplifier according to claim 1, further comprising loads coupled to drain terminals of the first and second transistors.

3. The differential amplifier according to claim 1, further comprising an in-phase signal generating unit configured to average the first and second input signals and thereby generate the in-phase signal,
wherein the in-phase signal generating unit is coupled to the in-phase signal input terminal.

4. The differential amplifier according to claim 3, wherein,
the in-phase signal generating unit includes third and fourth transistors having source terminals coupled to each other at a second common node and drain terminals coupled to each other at a third common node, and a second common current source coupled to the second common node; and
in the in-phase signal generating unit, the in-phase signal is supplied from the third common node to the in-phase signal input terminal.

5. The differential amplifier according to claim 4, wherein,
the in-phase signal generating unit further includes fifth and sixth transistors, and the fifth and sixth transistors are coupled to the sources of the third and fourth transistors at the second common node;
gates of the third and fifth transistors receive a third input signal, and gates of the fourth transistor and sixth transistor receive a fourth input signal; and
a drain of the fifth transistor is coupled to the gate of the first transistor, and a drain of the sixth transistor is coupled to the gate of the second transistor, and the in-phase signals of the third and fourth input signals are supplied to the in-phase signal input terminal.

6. The differential amplifier according to claim 3, further comprising an in-phase signal buffer configured to buffer the in-phase signal outputted from the in-phase signal generating unit,
wherein the in-phase signal buffer is coupled to the in-phase signal input terminal.

7. The differential amplifier according to claim 6, wherein,
the in-phase signal buffer includes a seventh transistor; and
a source follower made up of the seventh transistor buffers the in-phase signal.

8. The differential amplifier according to claim 3, further comprising a differential signal output unit configured to output a differential signal,
wherein the in-phase signal generating unit includes first and second resistors used to generate an intermediate potential relative to the differential signal; and
in the in-phase signal generating unit, the in-phase signal is outputted from an intermediate node of the first and second resistors to the in-phase signal input terminal.

9. The differential amplifier according to claim 8, wherein
the in-phase signal generating unit further includes eighth and ninth transistors;
the first and second resistors are coupled between source terminals of the eighth and ninth transistors;
one signal of the differential signal is inputted to a gate terminal of the eighth transistor, and the other signal of the differential signal is inputted to a gate terminal of the ninth transistor;
one signal of the differential signal is inputted to the gate terminal of the first transistor, and the other signal of the differential signal is inputted to the gate terminal of the second transistor; and
the in-phase signal generating unit outputs the in-phase signal of the two signals of the differential signal to the in-phase signal input terminal.

10. The differential amplifier according to claim 1, wherein
the first and second transistors are each an nMOS transistor or a PMOS transistor.

11. The differential amplifier according to claim 1, wherein
a capacitor is coupled between the in-phase signal input terminal and the common node.
